(19) United States
(12) Patent Application Publication
(10) Pub. No.: US 2026/0068582 A1
(43) Pub. Date: Mar. 5, 2026

(54) SEMICONDUCTOR MANUFACTURING SYSTEM AND METHOD FOR MANUFACTURING SEMICONDUCTOR DEVICE

(71) Applicant: Kioxia Corporation, Tokyo (JP)

(72) Inventors: Junji KATAOKA, Kawasaki (JP); Koji ASAKAWA, Kawasaki (JP); Kazuaki KURIHARA, Yokohama (JP); Daiki IINO, Yokohama (JP); Yuma KATO, Yokohama (JP); Naoyoshi YAMAMOTO, Yokkaichi (JP); Makoto OSANAI, Yokkaichi (JP)

(73) Assignee: Kioxia Corporation, Tokyo (JP)

(21) Appl. No.: 19/079,762

(22) Filed: Mar. 14, 2025

(30) Foreign Application Priority Data
Sep. 5, 2024 (JP) 2024-153436

(51) Int. Cl. H01L 21/67

(52) U.S. Cl. CPC H01L 21/67075

(57) ABSTRACT

A semiconductor manufacturing system and a method are capable of restraining a pattern on a semiconductor substrate from collapsing while performing wet etching on the semiconductor substrate. As an example, a semiconductor manufacturing system includes a first fluid reservoir that retains a first fluid generated by adding, to a first liquid, an adjusting substance for adjusting a pH. The first fluid supplier supplies the first fluid to a mixer. A second fluid supplier causes a second fluid to turn into a supercritical fluid and supplies the supercritical fluid to the mixer. A first heating mechanism houses the mixer and heats the mixer. A second heating mechanism heats a chamber capable of housing a substrate. A fluid mixture supplier supplies the second heating mechanism with a fluid mixture into which the first fluid and the supercritical fluid are mixed in the mixer.

### CROSS-REFERENCE TO RELATED APPLICATIONS

This application is based upon and claims the benefit of priority from Japanese Patent Application No. 2024-153436, filed Sep. 5, 2024, the entire contents of which are incorporated herein by reference.

### FIELD

Embodiments described herein relate generally to a semiconductor manufacturing system and a method for manufacturing a semiconductor device.

### BACKGROUND

In the step of performing wet etching on a semiconductor wafer, a pattern on a substrate may collapse while the semiconductor wafer is dried.

### BRIEF DESCRIPTION OF THE DRAWINGS

FIG. 1 is a phase diagram illustrating the relationship among pressure, temperature, and phase states of a substance.

FIG. 2 is a block diagram illustrating a configuration example of an etching system according to the present embodiment.

FIG. 3 is a sectional view illustrating a step to replace sacrificial films in a memory cell array of a NAND flash memory with electrode films.

FIG. 4 is a sectional view illustrating the replacement step subsequent to FIG. 3.

FIG. 5 is a sectional view illustrating the replacement step subsequent to FIG. 4.

FIG. 6 is a sectional view illustrating the replacement step subsequent to FIG. 5.

FIG. 7 is a sectional view illustrating the replacement step subsequent to FIG. 6.

FIG. 8A is a graph illustrating a relationship between pH and etching rate.

FIG. 8B is a graph illustrating a relationship between pH and etching rate.

FIG. 9 is a graph illustrating the temperature dependence of the optimal pH value of a first fluid.

FIG. 10 is a top view illustrating a configuration example of a mixer.

FIG. 11A is a graph illustrating changes in the film thickness of a silicon nitride film before and after treatment using the mixer.

FIG. 11B is a graph illustrating changes in the film thickness of a silicon nitride film before and after treatment not using the mixer.

FIG. 12A is a graph illustrating changes in the film thickness of a silicon nitride film before and after the treatment that was performed for 5 min under conditions of 300° C. and 10 MPa with a supercritical CO₂ and a fluid with its pH adjusted to pH=2 by adding formic acid to H₂O that were mixed together using the mixer.

FIG. 12B is a graph illustrating changes in the film thickness of a silicon oxide film before and after the treatment under the same conditions as in the case of FIG. 12A.

FIG. 13 is a sectional view illustrating a configuration example of a semiconductor memory device to be manufactured in the present embodiment.

FIG. 14 is a plan view illustrating a stacked body.

FIG. 15 is a sectional view exemplifying a memory cell in a three-dimensional structure.

FIG. 16 is a sectional view exemplifying the memory cell in a three-dimensional structure.

FIG. 17 is a sectional view illustrating an example of a replacement step in a manufacturing process of an array chip according to the present embodiment.

FIG. 18 is a sectional view illustrating the replacement step subsequent to FIG. 17.

FIG. 19 is a sectional view illustrating the replacement step subsequent to FIG. 18.

FIG. 20 is a sectional view illustrating the replacement step subsequent to FIG. 19.

### DETAILED DESCRIPTION

There are provided a semiconductor manufacturing system and a method for manufacturing a semiconductor device that are capable of restraining a pattern on a semiconductor substrate from collapsing while performing wet etching on the semiconductor substrate.

In general, according to one embodiment, a semiconductor manufacturing system according to the present embodiment includes a first fluid reservoir (tank, or tub) that retains a first fluid generated by adding, to a first liquid, an adjusting substance for adjusting a pH. The first fluid supplier (source, or pump) supplies the first fluid to a mixer. A second fluid supplier (source, or pump) causes a second fluid to turn into a supercritical fluid and supplies the supercritical fluid to the mixer. A first heating mechanism houses the mixer and heats the mixer. A second heating mechanism heats a chamber capable of housing a substrate. A fluid mixture supplier supplies the second heating mechanism with a fluid mixture into which the first fluid and the supercritical fluid are mixed in the mixer.

An embodiment according to the present disclosure will be described below with reference to the drawings. The present embodiment is exemplary and not intended to limit the present disclosure. The drawings are schematic or conceptual. In the description and drawings, the same components are denoted by the same reference characters.

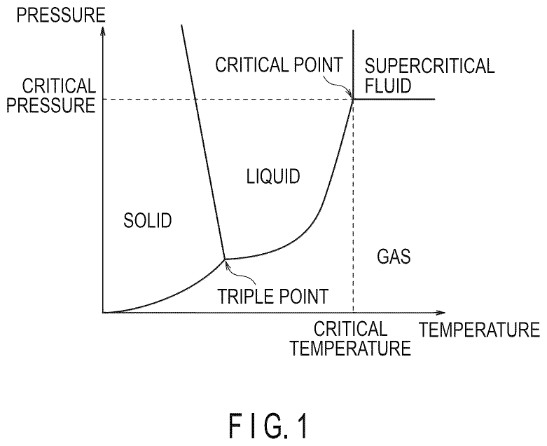

First, supercritical fluid will be described. FIG. 1 is a phase diagram illustrating the relationship among pressure, temperature, and phase states of a substance. A functional substance of a supercritical fluid includes three states of existence: a vapor phase (gas), a liquid phase (liquid), and a solid phase (solid), which are referred to as three states.

As illustrated in FIG. 1, the above three phases are partitioned into by a vapor pressure curve (gas-phase equilibrium curve), which indicates a boundary between the vapor phase and the liquid phase, a sublimation curve, which indicates a boundary between the vapor phase and the solid phase, and a fusion curve, which indicates a boundary between the solid phase and the liquid phase. These three phases meet at a triple point. From the triple point, the vapor pressure curve extends toward the high temperature side to reach a critical point, the limit up to which the vapor phase and the liquid phase can coexist. At the critical point, the densities of the vapor phase and the liquid phase are equal, and the interface of the vapor-liquid coexistence state disappears.

At higher temperature and pressure than the critical point, the vapor phase and the liquid phase are no longer distinguishable, and the substance turns into a supercritical fluid. The supercritical fluid is a fluid of which the temperature and the pressure are higher than the critical point. The supercritical fluid resembles a gas in that the diffusion strength of its solvent molecules is dominant. In contrast, the supercritical fluid resembles a liquid in that the cohesive strength of its molecules has considerable influence. Thus, the supercritical fluid is of such a nature that it dissolves various substances.

The supercritical fluid has such characteristics that it has a weak surface tension compared with a liquid and thus easily permeates a microstructure.

When the supercritical fluid is dried in such a manner as to make a direct transition from its supercritical state to its vapor phase, the interface between its gas and liquid does not occur, that is, a capillary force (surface tension) does not act, and it is thus possible to perform the drying without damaging the microstructure. By taking advantage of such a supercritical state of the supercritical fluid, it is possible to dry a substrate without causing its microstructure to collapse (supercritical drying).

As the supercritical fluid, for example, carbon dioxide, ethanol, methanol, propanol, butanol, methane, ethane, propane, water, ammonia, ethylene, fluoroalkane such as carbon tetrafluoride, sulfur hexafluoride, or the like is selected.

For example, carbon dioxide has a critical temperature of 31.1° C. or higher and a critical pressure of 7.37 MPa or higher, which are relatively low temperature and low pressure, respectively. Thus, carbon dioxide can be easily used for treatment.

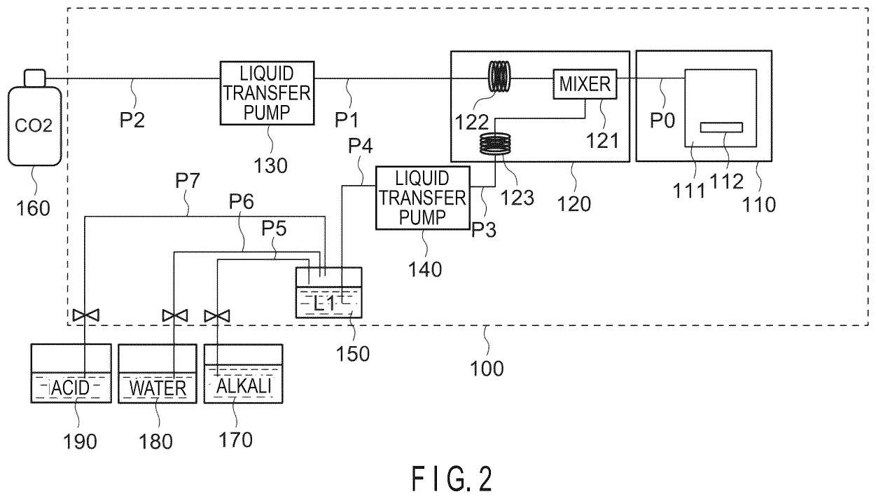

FIG. 2 is a block diagram illustrating a configuration example of an etching system 100 according to the present embodiment. The etching system 100 according to the present embodiment generates a first fluid by adding an adjusting substance for adjusting a pH to water, turns carbon dioxide as a second fluid into a supercritical fluid, and mixes the supercritical fluid and the first fluid together. The etching system 100 heats a fluid mixture of the supercritical fluid and the first fluid to a predetermined temperature at a predetermined pressure and uses the heated fluid mixture as an etchant. For example, the fluid mixture is used for selectively etching a silicon nitride film relative to a silicon oxide film.

The etching system 100 includes heating mechanisms 110 and 120, a chamber 111, a mixer 121, heaters 122 and 123, liquid transfer pumps 130 and 140, and a first fluid reservoir 150. Note that a CO₂ reservoir 160, pH adjusting substance reservoirs 170 and 190, and a water reservoir 180 may be provided inside the etching system 100 or may be provided outside the etching system 100 in a replaceable manner.

The heating mechanism 110 has a function of heating the inside of the chamber 111. For example, the heating mechanism 110 is a housing such as an oven or a furnace. The heating mechanism 110 is capable of freely controlling the temperature of the inside of the chamber 111.

The chamber 111 is a hollow container capable of housing a semiconductor substrate. The chamber 111 is made of a material that is resistant to damage from pressurizing and heating by the heating mechanism 110 (e.g., a metal such as a stainless steel). In the chamber 111, there is provided a stage 112 on which the semiconductor substrate can be placed. The heating mechanism 110 is also capable of controlling the temperature of the stage 112. In the chamber 111, the semiconductor substrate (not illustrated) is placed on the stage 112 and subjected to etching treatment at the predetermined pressure and the predetermined temperature.

The heating mechanism 120 has a function of heating the inside of the mixer 121. For example, the heating mechanism 120 is a housing such as an oven or a furnace. The heating mechanism 120 is capable of freely controlling the temperature of the inside of the mixer 121 and the temperature of fluid passing through pipes P1 and P3.

The mixer 121 mixes the supercritical fluid from the pipe P1 and the first fluid from the pipe P3 to generate the fluid mixture. The fluid mixture is supplied to the chamber 111 from the mixer 121 through a pipe P0 by the liquid transfer pumps 130 and 140. The pipe P0 functions as a fluid mixture supplier.

The heater 122 is provided in the pipe P1 that provides a piping connection between the liquid transfer pump 130 and the mixer 121. The heater 122 maintains the fluid passing through the pipe P1 at a predetermined temperature. The heater 123 is provided in the pipe P3 that provides a piping connection between the liquid transfer pump 140 and the mixer 121. The heater 123 maintains the fluid passing through the pipe P3 at a predetermined temperature. The heaters 122 and 123 are, for example, flexible tubes.

The liquid transfer pump 130 functions as a fluid supplier that supplies carbon dioxide in the form of a fluid from a pipe P2 through the pipe P1 to the mixer 121. The liquid transfer pump 130 sends the carbon dioxide in the form of a fluid to the pipe P1. At that time, the liquid transfer pump 130 pressurizes the carbon dioxide by compressing the carbon dioxide inside the pipe P1, thereby turning the carbon dioxide from a fluid into a supercritical fluid. The carbon dioxide in the form of a supercritical fluid passes through the pipe P1, is heated by the heating mechanism 120, and then is supplied to the mixer 121.

The CO₂ reservoir 160 is provided with a piping connection to the liquid transfer pump 130 by the pipe P2. The CO₂ reservoir 160 retains the carbon dioxide in the form of a fluid and supplies the carbon dioxide in the form of a fluid through the pipe P2 to the liquid transfer pump 130.

The liquid transfer pump 140 functions as a fluid supplier that supplies a first fluid L1 from a pipe P4 through the pipe P3 to the mixer 121. The liquid transfer pump 140 sends the first fluid L1 to the pipe P3, and at that time, the liquid transfer pump 140 pressurizes the first fluid L1 by compressing the first fluid L1 inside the pipe P3. The first fluid L1 passes through the pipe P3, is heated by the heating mechanism 120, and then is supplied to the mixer 121.

The first fluid reservoir 150 is connected to pipes P4 to P6. The first fluid reservoir 150 receives a pH adjusting substance from the pH adjusting substance reservoir 170 or 190 through a pipe P5 or P7 and receives water from the water reservoir 180 through a pipe P6. The first fluid reservoir 150 is, for example, a tank or a tub. The first fluid reservoir 150 adds the pH adjusting substance supplied from the pH adjusting substance reservoir 170 or 190 to the water supplied from the water reservoir 180, thus generating the first fluid L1. The first fluid reservoir 150 supplies the first fluid L1 through the pipe P4 to the liquid transfer pump 140.

The pH adjusting substance reservoir 170 is connected to the pipe P5. The pH adjusting substance reservoir 170 retains an alkali that is an adjusting substance for adjusting the pOH of the first fluid. The pH adjusting substance reservoir 170 is, for example, a tank or a tub. As described later, OH⁻ plays a major role in a reaction involved in etching in the present embodiment. Therefore, the concentration of OH⁻ is important. The pH adjusting substance reservoir 170 supplies the pH adjusting substance through the pipe P5 to the first fluid reservoir 150. The pH adjusting substance retained in the pH adjusting substance reservoir 170 is, for example, a substance such as an amine at least one of hexylamine, pyridine, aniline, ammonia, sodium hydroxide, potassium hydroxide, and calcium hydroxide, which supplies the first fluid with alkali to make the first fluid alkaline.

The pH adjusting substance reservoir 190 is connected to the pipe P7. The pH adjusting substance reservoir 190 retains an acid that is a pH adjusting substance for adjusting the pOH of the first fluid. The pH adjusting substance reservoir 190 is, for example, a tank or a tub. As mentioned above, the concentration of OH⁻ is important in the reaction. In a supercritical state or a subcritical state, the negative logarithm of the ion product constant which is the product of the concentrations of H⁺ and OH⁻, pkw, decreases. At this time, pOH is adjusted by adding H⁺ such that the concentration of OH⁻ does not increase. The pH adjusting substance reservoir 190 supplies the pH adjusting substance through the pipe P7 to the first fluid reservoir 150. The adjusting substance retained in the pH adjusting substance reservoir 190 is, for example, a substance at least one of acetic acid, formic acid, hydrochloric acid, sulfuric acid, nitric acid, phosphoric acid, oxalic acid, and benzoic acid, which supplies the first fluid with acid to make the first fluid acidic. Note that hydrofluoric acid or hydrogen fluoride cannot be used because hydrofluoric acid and hydrogen fluoride accelerate the etching of SiO₂ in the presence of water.

The water reservoir 180 is connected to the pipe P6. The water reservoir 180 retrains the water. The water reservoir 180 is, for example, a tank or a tub. The water reservoir 180 supplies the water through the pipe P6 to the first fluid reservoir 150.

Although not illustrated, a surface active agent may be added to the first fluid reservoir 150. That is, the first fluid L1 may include the surface active agent. A desirable surface active agent is, for example, a surface active agent with long fluorocarbon chains or highly branched fluorocarbon chains.

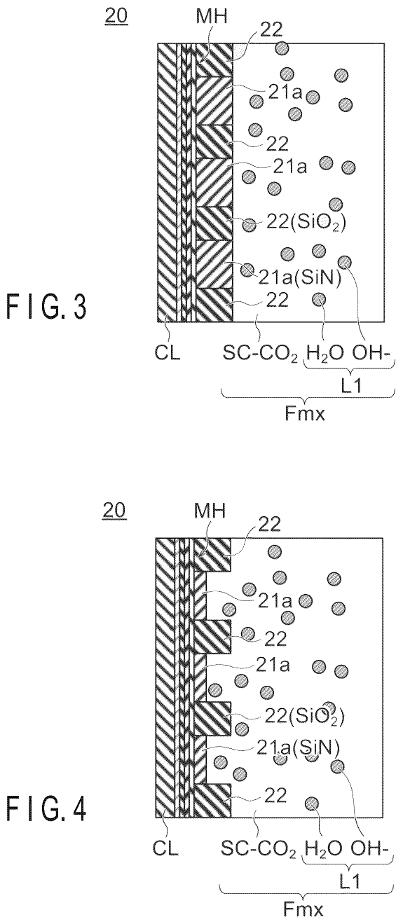

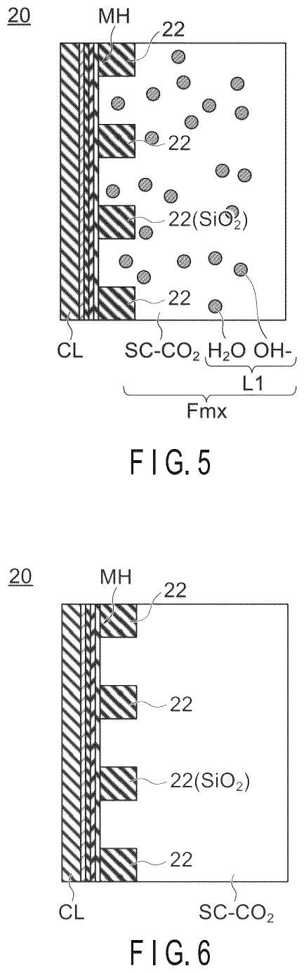

FIG. 3 to FIG. 7 are sectional views illustrating a step to replace sacrificial films 21a in a memory cell array of a NAND flash memory with electrode films 21. Note that the replacement step will be described in detail later.

In the replacement step, the sacrificial films 21a (e.g., silicon nitride films) are selectively removed from a stacked body 20 that is formed by alternately stacking the sacrificial films 21a and the insulation films 22 (e.g., silicon oxide films). At this time, a semiconductor substrate is carried into the chamber 111 of the etching system 100 according to the present embodiment and placed on the stage 112 in the chamber 111. CL denotes a columnar body forming memory cells.

The etching system 100 supplies the inside of the chamber 111 with the fluid mixture (hereinafter, referred to as a “fluid mixture Fmx”) of the above supercritical fluid (hereinafter, referred to as a “supercritical fluid SC-CO₂”) and the first fluid L1. The supercritical fluid SC-CO₂ is carbon dioxide in a supercritical state. The first fluid L1 is a liquid made by adding an acid or an alkali serving as the pH adjusting substance to water (H₂O). The fluid mixture Fmx is generated by mixing the supercritical fluid SC-CO₂ and the first fluid L1 in a predetermined ratio at a predetermined pressure and a predetermined temperature. The pH or pOH of the fluid mixture Fmx is adjusted such that the sacrificial films 21a (e.g., silicon nitride films) are selectively etched relative to the insulation films 22 (e.g., silicon oxide films).

The fluid mixture Fmx is generated by mixing the supercritical fluid SC-CO₂ into the first fluid L1. Therefore, for example, when the pH of the first fluid is greater than or equal to two, the fluid mixture Fmx has a pH that is approximately three to four units lower than that of the first fluid L1. In other words, in the first fluid reservoir 150, the pH of the first fluid L1 is adjusted based on an optimal pH that is determined in advance backward from a change in pH caused by the mixing of the supercritical fluid SC-CO₂. For example, pH information that specifies the relationship between etching temperature and the optimal pH value of the first fluid L1 may be saved in a controller or the like of the etching system 100, wherein the controller controls operations of the components of FIG. 2. The controller may be one or more CPUs with a memory and computer code (collectively “control circuitry”) that once executed by the one or more CPUs causes the one or more CPUs to execute the control procedures described herein. In addition, the first fluid reservoir 150 may be provided with a pH measurement monitor, the pH of the first fluid L1 may be adjusted base on the saved pH information and an etching temperature for a wafer to be subjected to etching treatment.

As illustrated in FIG. 3 to FIG. 5, when the stacked body 20 is exposed to the fluid mixture Fmx, the sacrificial films 21a are selectively etched by the first fluid L1.

After the sacrificial films 21a are removed, the first fluid reservoir 150 and the liquid transfer pump 140 stop the supply of the first fluid L1. The first fluid reservoir 150 and the liquid transfer pump 130 supply the inside of the chamber 111 with only the supercritical fluid SC-CO₂, which has a surface tension lower than that of liquid. This removes the first fluid L1 and supplies the supercritical fluid SC-CO₂ between the insulation films 22. Thus, as illustrated in FIG. 6, moisture is discharged from the area surrounding the stacked body 20, and the area surrounding the stacked body 20 is filled with the supercritical fluid SC-CO₂.

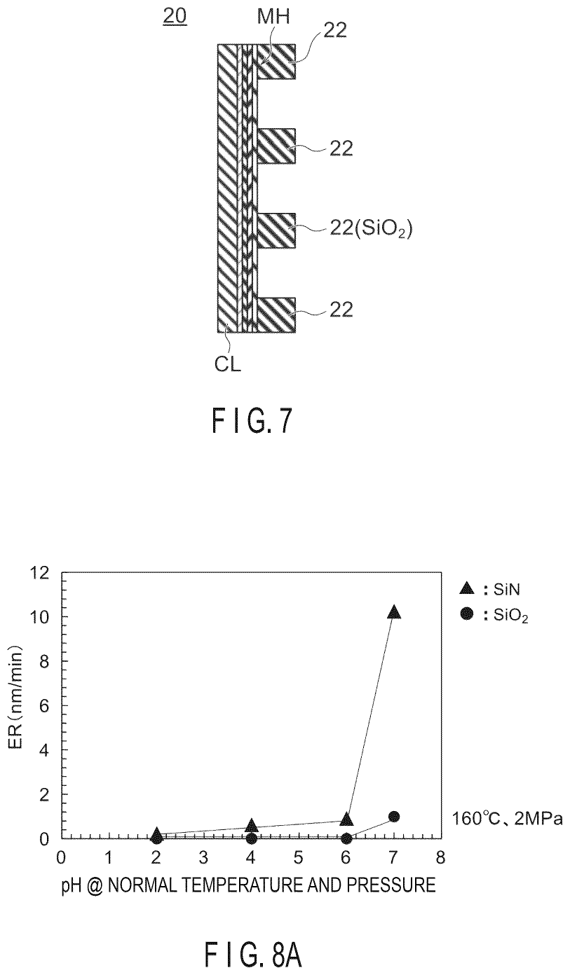

Next, as illustrated in FIG. 7, the atmospheric pressure in the chamber 111 is reduced to vaporize the supercritical fluid SC-CO₂. Since the surface tension of the supercritical fluid SC-CO₂ is lower than that of the first fluid L1, it is possible to remove the supercritical fluid SC-CO₂ to dry the stacked body 20 while restraining the surface tension from acting between the insulation films 22. As a result, it is possible to restrain the insulation films 22 from collapsing.

Next, the adjustment of the pH of the first fluid L1 will be described.

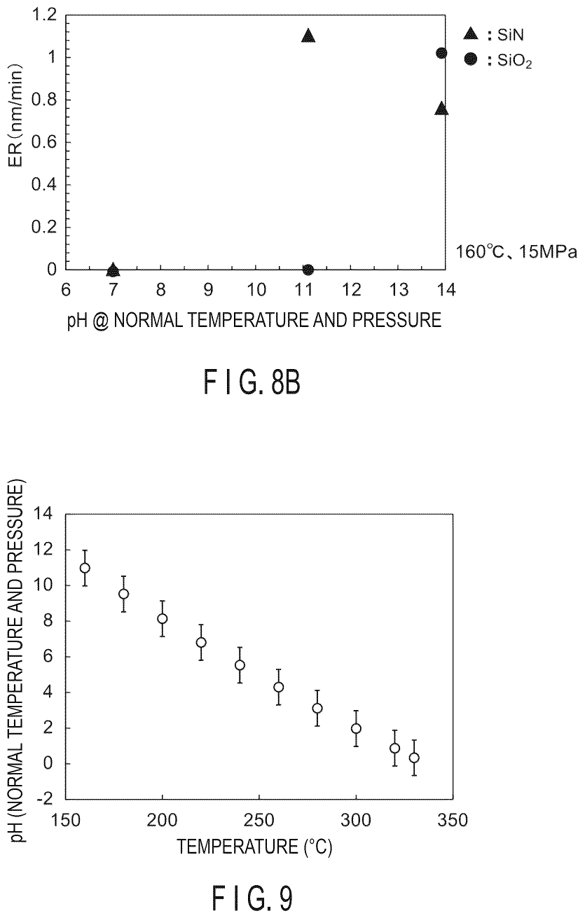

FIG. 8A and FIG. 8B are graphs each illustrating a relationship between the pH and etching rate. The vertical axis of FIG. 8A represents the etching rates of a silicon oxide film (SiO₂) and a silicon nitride film (SiN) when the first fluid L1 having the pH specified on the horizontal axis at normal temperature and pressure is used at an etching temperature of about 160° C.

The vertical axis of FIG. 8B represents the etching rates of a silicon oxide film and a silicon nitride film when the fluid mixture Fmx made by mixing the first fluid L1 and CO₂ and having the pH specified on the horizontal axis at normal temperature and pressure is used at an etching temperature of about 160° C. The etching temperature is the temperature of the fluid mixture or the stage 112 during the etching. Note that FIG. 8A illustrates etching rates of the case where the treatment was performed without mixing CO₂ and the water with an adjusted pH (the first fluid L1), as comparative examples. FIG. 8B illustrates etching rates of the fluid mixture Fmx according to the present embodiment. Circles indicate etching rates of the silicon oxide film. Triangles indicate etching rates of the silicon nitride film.

According to the graph in FIG. 8A, in the case where the first fluid L1 and CO₂ are not mixed together, it is possible to etch the silicon nitride film without etching the silicon oxide film at a pH (normal temperature) of about six. That is, at a pH (normal temperature) of about six, an etching ratio (the etching rate of the silicon nitride film/the etching rate of the silicon oxide film) can be made significantly high.

In contrast, the etching rate of the silicon nitride film is high at a pH (normal temperature) of about seven. However, the silicon oxide film is also etched, and thus the etching ratio is lower than at a pH (normal temperature) of about six.

Conversely, as the pH (normal temperature) is decreased from six, the etching rate of the silicon oxide film is maintained at substantially zero, while the etching rate of the silicon nitride film itself gradually becomes lower. Therefore, as the pH (normal temperature) is decreased from six, the etching ratio also becomes lower. Accordingly, in the case where the water of which the pH is adjusted with an acid is used as the etchant, the pH (normal temperature) being about six is considered preferable. This is because in a supercritical state or a subcritical state, the negative logarithm of the ion product constant which is the product of the concentrations of H⁺ and OH⁻, pkw, decreases, and a pH=6 at normal temperature brings the concentration of OH⁻, which is important in the etching reaction, in the supercritical state or the subcritical state into a preferable condition.

In contrast, as illustrated in FIG. 8B, in the case where the fluid mixture Fmx is used as the etchant, when the pH (normal temperature) of the first fluid L1 is about 11 to 12, it is possible to restrain the silicon oxide film from being etched and to etch the silicon nitride film, and the etching selectivity can be made significantly high when the pH (normal temperature) of the first fluid L1 is about 11 to 12.

In contrast, when the pH (normal temperature) of the first fluid L1 is made higher than 12, the etching rate of the silicon oxide film becomes high, which makes the etching selectivity low.

Conversely, when the pH (normal temperature) of the first fluid L1 is decreased from 11, the etching rate of the silicon oxide film is maintained at substantially zero, while the etching rate of the silicon nitride film itself gradually becomes lower. Therefore, when the pH (normal temperature) of the first fluid L1 is decreased from 11, the etching ratio also becomes lower. Accordingly, in the case where the fluid mixture Fmx is used as the etchant, the pH (normal temperature) of the first fluid L1 is preferably about 11 to 12. Furthermore, the etching ratio reaches its peak when the pH (normal temperature) of the first fluid L1 is 11.11.

As seen from the above, in the case where the fluid mixture Fmx is used, the etching ratio can be made high at an etching temperature of 160 degrees by adjusting the pH (normal temperature) of the first fluid L1 to an alkaline level of about 11 to 12.

Here, the etching of a silicon nitride film by water is expressed as the following chemical formula.

Si₃N₄+12H₂O+4H⁺→3Si(OH)₄+4NH₄⁺ (Formula 1)

The process of the above etching requires OH-because the silicon nitride film is dissolved in the form of Si(OH)₄. At high temperature, water ionizes to more H⁺ and OH⁻. The multiplication of an increase in the amount of OH⁻ generated at this time and an increase in reaction rate due to the temperature promotes the etching of the silicon nitride film.

In contrast, when the water is mixed into the supercritical fluid SC-CO₂, carbon dioxide is dissolved in the water to generate carbonic acid, H₂CO₃. In this case, H⁺ is generated, and OH⁻ is reduced. The reduction in OH⁻ decreases the etching rate of the silicon nitride film. Hence, in the present embodiment, the first fluid L1 is generated by adding the pH adjusting substance to water so as to compensate for the reduction in OH⁻. The first fluid L1 supplements OH⁻ to the fluid mixture Fmx, making the fluid mixture Fmx alkaline. At an etching temperature of 160 degrees, by adjusting the pH (normal temperature) of the first fluid L1 to a level of about 11.11, the etching ratio of the silicon nitride film to the silicon oxide film can be made high.

FIG. 9 is a graph illustrating the temperature dependence of the optimal pH value of the first fluid L1. The horizontal axis represents etching temperature (C). The vertical axis represents the optimal pH value of the first fluid L1 at normal temperature and pressure. The optimal pH value of the first fluid L1 is a pH value at which the etching ratio of the silicon nitride film to the silicon oxide film by the fluid mixture is maximized. As described with reference to FIG. 8, the optimal pH value of the first fluid L1 at an etching temperature of 160 degrees is about 11.11.

According to the graph in FIG. 9, the optimal pH value of the first fluid is given by the following Expression 1. The optimal pH value of the first fluid at each of treatment temperatures can be illustrated as in the graph in FIG. 9.

pH=−32.13×ln(T)+206.03 (Expression 1)

Here, T denotes the temperature of the etching treatment (K: Kelvin).

When the etching temperature is within the range of about 140° C. to about 330° C., the optimal pH values are provided. If the etching temperature is lower than about 140° C., the etching rate of the silicon nitride film is excessively slow. If the etching temperature is higher than about 330° C., the etching rate of the silicon oxide film is increased, which decreases the etching selectivity of the silicon nitride film to the silicon oxide film. Accordingly, the etching temperature is preferably within the range of about 140° C. to about 330° C.

When the etching temperature is about 140° C. to about 220° C., the optimal pH value of the first fluid at normal temperature and pressure is at an alkaline level. When the etching temperature is about 220° C. to about 330° C., the optimal pH value of the first fluid at normal temperature and pressure is at an acidic level. In the case where the first fluid is made acidic, the etching temperature is preferably about 250° C. to about 300° C. This is because the reaction rate of etching of the silicon oxide film by OH⁻ is increased, and it is thus necessary to increase the concentration of H⁺ to decrease the concentration of OH⁻.

As seen from the above, in the present embodiment, it is possible to maintain a high etching selectivity of the silicon nitride film to the silicon oxide film by setting the pH of the first fluid. In addition, using the fluid mixture including the supercritical fluid SC-CO₂ can restrain the insulation films 22 from collapsing during drying after the etching.

In the case where the treatment temperature is expressed in Kelvin, for example, when the treatment temperature is between 413 K and 473 K, inclusive, the pH of the first fluid L1 is 11 to 8 at normal temperature and pressure. For example, when the treatment temperature is between 473 K and 503 K, inclusive, the pH of the first fluid L1 is 8 to 6 at normal temperature and pressure. For example, when the treatment temperature is between 553 K and 593 K, inclusive, the pH of the first fluid L1 is 3 to 1 at normal temperature and pressure.

Note that in the case where the optimal pH value is at an alkaline level, the etching of the silicon oxide film can be stopped by the pH adjusting substance reservoirs 170 and 190 shifting the pH of the first fluid to an acidic level. Conversely, the etching of the silicon oxide film can be started by the pH adjusting substance reservoirs 170 and 190 shifting the pH of the first fluid to an alkaline level. As seen from the above, the etching system 100 according to the present embodiment may use the pH of the first fluid to control the start or stop of the etching treatment.

The etching pressure is preferably about 7.38 MPa to about 15 MPa. The lower limit of the etching pressure needs to be at least 7.38 MPa, which is the critical pressure of carbon dioxide. Regarding the upper limit of the etching pressure, if the etching pressure is high, turbulence occurs, leading to nonuniform etching. Furthermore, the etching pressure is preferably about 10 MPa. This is for restraining the turbulence to prevent the nonuniform etching.

As the adjusting substance, for example, an amine such as hexylamine, pyridine, aniline, ammonia, sodium hydroxide, potassium hydroxide, calcium hydroxide, or the like may be used to make the first fluid alkaline.

In contrast, the pH adjusting substance is preferably Bronsted acid, of which the boiling point is about 140° C. or lower, or a carboxylic acid of which the functional group R has a valency of 6 or less to make the first fluid acidic. Preferable examples of the adjusting substance include acetic acid (boiling point: 118° C.), formic acid (boiling point: 108° C.), and hydrochloric acid (boiling point: −85.09° C.). This enables the pH adjusting substance to be easily removed from the semiconductor substrate after the etching at an etching temperature of about 140° C. to about 330° C.

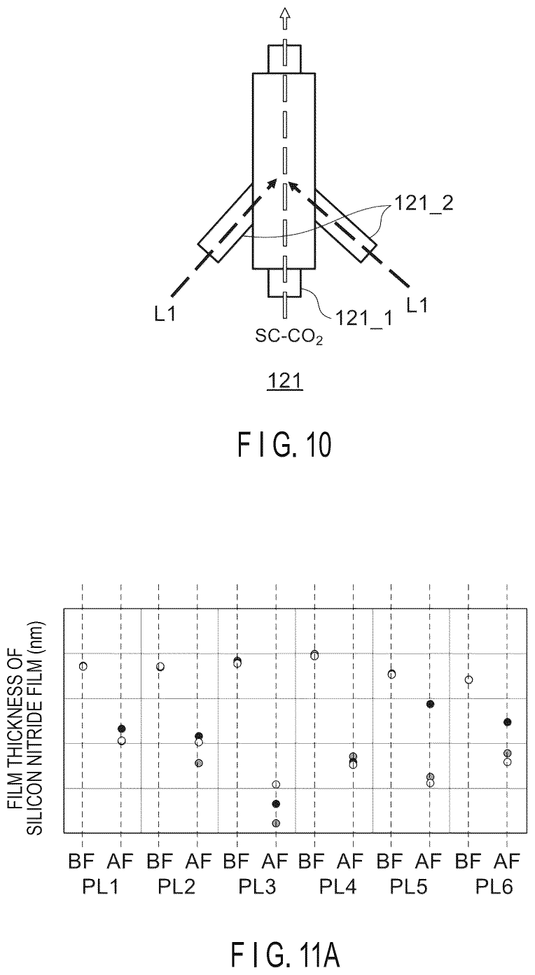

FIG. 10 is a top view illustrating a configuration example of the mixer 121. The mixer 121 includes a main channel 121_1 and a plurality of sub channels 121_2. The diameter of the main channel 121_1 is larger than that of the sub channels 121_2. Through the main channel 121_1, the supercritical fluid SC-CO₂ and the fluid mixture flow. The plurality of sub channels 121_2 are provided with piping connection to the main channel 121_1 and supply the first fluid L1 to the main channel 121_1. The plurality of sub channels 121_2 are connected obliquely to the main channel 121_1 to cause the first fluid L1 to flow into the main channel 121_1 in a direction in which the supercritical fluid SC-CO₂ and the fluid mixture flow. In addition, the plurality of sub channels 121_2 are provided in bilateral symmetry with respect to the main channel 121_1 as viewed from above. This causes the first fluid L1 from the plurality of sub channels 121_2 to be supplied to the supercritical fluid SC-CO₂ flowing through the main channel 121_1 from both lateral sides. As a result, the first fluid L1 and the supercritical fluid SC-CO₂ produce a swirl flow, by which the first fluid L1 and the supercritical fluid SC-CO₂ are forcibly mixed together into the fluid mixture.

Although not illustrated, the mixer 121 may be a container that retains a surface active agent. In this case, the surface active agent mixes the supercritical fluid SC-CO₂ and the first fluid L1 together to generate the fluid mixture. A desirable surface active agent is, for example, a surface active agent with long fluorocarbon chains or highly branched fluorocarbon chains.

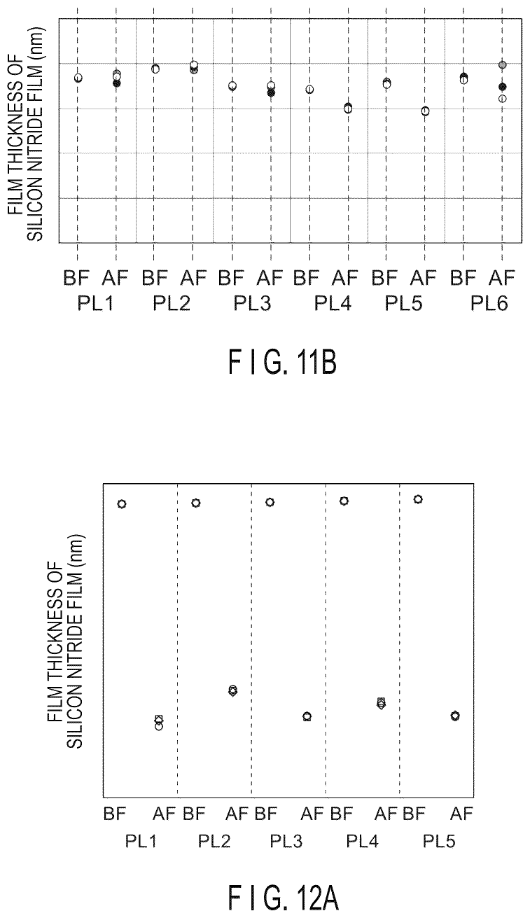

FIG. 11A is a graph illustrating changes in the film thickness of a silicon nitride film before and after the treatment using the mixer. FIG. 11B is a graph illustrating changes in the film thickness of a silicon nitride film before and after the treatment not using the mixer. PL1 to PL6 indicate any positions in the course from the upstream and the downstream in the chamber 111 of the heating mechanism 110. BF and AF indicate a change in the film thickness of the silicon nitride film between a pre-etching state BF and a post-etching state AF at each of the positions PL1 to PL6.

According to FIG. 11A, the comparison between the pre-etching state BF and the post-etching state AF shows that the film thickness of the silicon nitride film changed at every position in the chamber 111. This indicates that the etching of the silicon nitride film progressed normally at every position in the chamber 111. That is, the mixer 121 forcibly mixing the supercritical fluid SC-CO₂ and the first fluid L1 together caused the etching of the silicon nitride film to be executed normally with the fluid mixture.

In contrast, according to FIG. 11B, the comparison between the pre-etching state BF and the post-etching state AF shows that the film thickness of the silicon nitride film hardly changed. This indicates that the etching of the silicon nitride film did not progress much. That is, since the mixer 121 was not provided, the supercritical fluid SC-CO₂ and the first fluid L1 were not mixed sufficiently, and the etching of the silicon nitride film was hardly executed.

As seen from the above, according to the present embodiment, the provision of the mixer 121 enables the generation of the fluid mixture into which the supercritical fluid SC-CO₂ and the first fluid L1 are sufficiently mixed together. This enables the etching system 100 to execute the etching of a silicon nitride film normally.

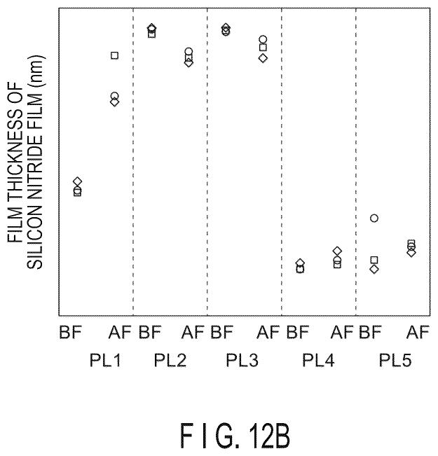

Note that FIG. 11A to FIG. 12B each illustrate the result of measurement at three points on a sample at the positions PL1 to PL6 in the chamber 111.

FIG. 12A is a graph illustrating changes in the film thickness of a silicon nitride film before and after the treatment that was performed for 5 min under conditions of 300° C. and 10 MPa with a supercritical CO₂ and a fluid with its pH adjusted to pH=2 by adding formic acid to H₂O that were mixed together using the mixer. FIG. 12B is a graph illustrating changes in the film thickness of a silicon oxide film before and after the treatment under the same conditions. PL1 to PL5 indicate up-down positions in the chamber 111 of the heating mechanism 110. BF and AF indicate a change in the film thickness between a pre-etching state BF and a post-etching state AF at each of the positions PL1 to PL5. Although the etching of the silicon nitride film progressed at every furnace position, no changes were found in the film thickness of the silicon oxide film (within a measurement error), and it can thus be confirmed that the etching of the silicon oxide film did not occur.

### (Semiconductor Memory Device)

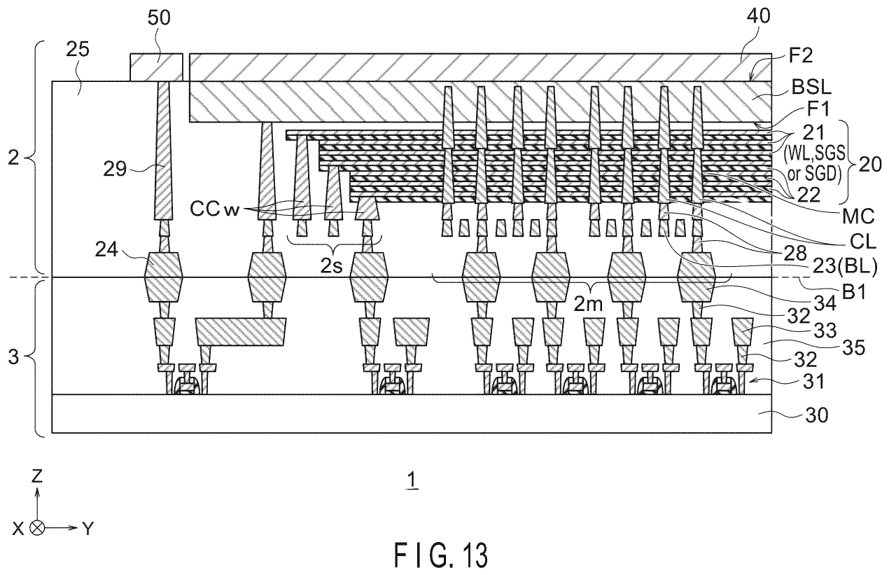

FIG. 13 is a sectional view illustrating a configuration example of a semiconductor memory device 1 to be manufactured in the present embodiment. Hereinafter, a stacking direction of a stacked body 20 is defined as a Z direction. A direction that intersects, for example, is perpendicular to the Z direction is defined as a Y direction. A direction that intersects, for example, is perpendicular to the Z direction and the Y direction is defined as an X direction. In FIG. 13, the semiconductor memory device 1 is shown, where a +Z direction is an upward direction. The semiconductor memory device 1 is, for example, a NAND flash memory.

The semiconductor memory device 1 includes an array chip 2 including a memory cell array and includes a CMOS chip 3 including a CMOS circuit. The array chip 2 and the CMOS chip 3 are bonded together at a bonding surface B1 and electrically connected to each other via wires that are joined at the bonding surface B1. FIG. 13 illustrates the state where the array chip 2 is provided on the CMOS chip 3.

The CMOS chip 3 includes a substrate 30, transistors 31, vias 32, wires 33 and 34, and an interlayer dielectric 35.

The substrate 30 is, for example, a semiconductor substrate such as a silicon substrate. Each of the transistors 31 is an N-type metal oxide semiconductor field effect transistor (MOSFET) or a P-type MOSFET provided on the substrate 30. The transistors 31 form, for example, complementary MOS (CMOS) circuitry that controls the memory cell array of the array chip 2. The plurality of transistors 31 form logic circuits such as sense amplifiers, row decoders, and column decoders. On the substrate 30, semiconductor elements other than the transistors 31, such as resistive elements and capacitive elements may be formed.

The vias 32 each electrically connect a transistor 31 and a wire 33 or electrically connect a wire 33 and a wire 34. The wires 33 and 34 form a multilayered interconnection structure in the interlayer dielectric 35. The wires 34 are embedded in the interlayer dielectric 35 and are exposed on a surface of the interlayer dielectric 35, being substantially flush with the surface. The wires 33 and 34 are electrically connected to the transistors 31 and the like. As the vias 32, and the wires 33 and 34, for example, a metal such as copper or tungsten is used. The transistors 31, the vias 32, and the wires 33 and 34 are covered with and protected by the interlayer dielectric 35. As the material of the interlayer dielectric 35, for example, an insulation film such as a silicon oxide film is used.

The array chip 2 includes the stacked body 20, columnar bodies CL, a source layer BSL, a metal layer 40, contact plugs CCw, contact plugs 29, bonding pads 50, wires 23 and 24, vias 28, and an interlayer dielectric 25.

The stacked body 20 is provided above the transistors 31 and is located in the +Z direction with respect to the substrate 30. The stacked body 20 is formed by stacking a plurality of electrode films 21 and a plurality of insulation films 22 alternately along the Z direction. The stacked body 20 forms the memory cell array together with the columnar bodies CL. As the material of the electrode films 21, for example, a conductive metal such as tungsten is used. As the material of the insulation films 22, for example, an insulation film such as a silicon oxide film is used. The insulation films 22 insulate the electrode films 21 from each other. That is, the plurality of electrode films 21 are stacked being insulated from each other. The numbers of stacked films of the electrode films 21 and the insulation films 22 are any numbers. The insulation films 22 may be each, for example, a porous insulation film or an air gap.

One or more of the electrode films 21 at the upper end of the stacked body 20 in the Z direction function as source-side selector gates SGS, and one or more of the electrode films 21 at the lower end of the stacked body 20 in the Z direction function as drain-side selector gates SGD. Electrode films 21 between the source-side selector gates SGS and the drain-side selector gates SGD function as word lines WL. The word lines WL are gate electrodes of memory cells MC. The source-side selector gates SGS are gate electrodes of source-side selection transistors. The drain-side selector gates SGD are gate electrodes of drain-side selection transistors. The source-side selector gates SGS are provided in an upper region of the stacked body 20. The drain-side selector gates SGD are provided in a lower region of the stacked body 20. The upper region refers to a region of the stacked body 20 farther from the CMOS chip 3 (closer to the metal layer 40), and the lower region refers to a region of the stacked body 20 closer to the CMOS chip 3.

The semiconductor memory device 1 includes pluralities of memory cells MC connected in series between source-side selection transistors and the drain-side selection transistors. Structures each including a source-side selection transistor, memory cells MC, and a drain-side selection transistor that are connected in series are called “memory strings” or “NAND strings.” The memory strings are connected to bit lines BL via, for example, vias 28. The bit lines BL are wires 23 that are provided below the stacked body 20 and extend in the X direction. Accordingly, the bit lines BL will be hereinafter also referred to as bit lines 23.

In the stacked body 20, a plurality of columnar bodies CL are provided. The columnar bodies CL extend in the stacked body 20 in such a manner as to penetrate the stacked body 20 in the stacking direction of the stacked body 20 (the Z direction) and are provided from vias 28 connected to the bit lines 23 to the source layer BSL. An internal structure of a columnar body CL will be described later. Note that FIG. 13 illustrates the case where columnar bodies CL are each formed in two segments in the Z direction. The columnar bodies CL may each be formed in three or more segments.

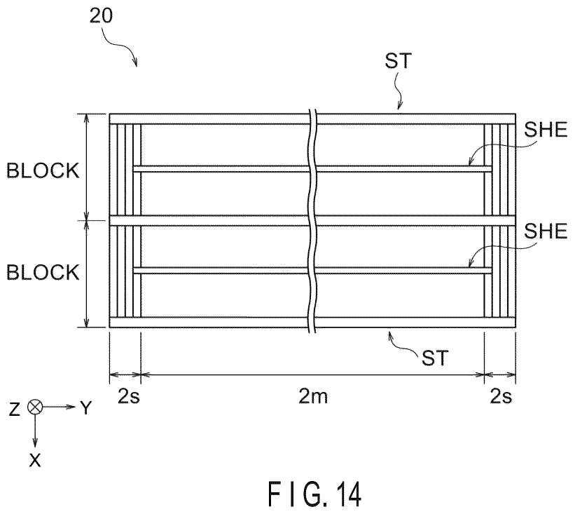

Although not illustrated in FIG. 13, a plurality of slits ST (see FIG. 14) are provided in the stacked body 20. The slits ST extend in the Y direction and penetrate the stacked body 20 in the stacking direction of the stacked body 20 (the Z direction). The slits ST are each filled with an insulation film such as a silicon oxide film, and the insulation film is formed in a plate shape. The slits ST electrically divide the electrode films 21 of the stacked body 20. Alternatively, the inner walls of the slits ST may be covered with insulation films such as silicon oxide films, and in addition, a conductive material may be embedded inside the insulation films. In this case, the conductive material can also function as source lines that reach the source layer BSL.

Above the stacked body 20, the source layer BSL is provided. The source layer BSL is provided corresponding to the stacked body 20. On a face F1 side of the source layer BSL, the stacked body 20 (a memory cell array 2m) is provided, and on a face F2 side, the opposite side, the metal layer 40 is provided. The source layer BSL is connected in common to one ends of a plurality of columnar bodies CL and provides a source voltage common to a plurality of columnar bodies CL in a single memory cell array 2m. That is, the source layer BSL functions as a common source electrode of the memory cell array 2m. As the material of the source layer BSL, for example, a conductive material such as a doped polysilicon is used. As the material of the metal layer 40, for example, a metallic material having a resistance lower than that of the source layer BSL, such as copper, aluminum, or tungsten, is used.

In a region that is above the face F2 of the source layer BSL and where the source layer BSL is not provided, the bonding pads 50 are provided. The bonding pads 50 are connected to metallic wires or the like (not illustrated) and receive power supply or signals from the outside of the semiconductor memory device 1. The bonding pads 50 are provided in such a manner as to be connected to one ends of the contact plugs 29 in the Z direction. The bonding pads 50 are connected to transistors 31 of the CMOS chip 3 via the contact plugs 29, wires 24, and wires 34. The transistors 31 are supplied with external power supplied through the bonding pads 50. Alternatively, the transistors 31 or the memory cell array 2m is supplied with signals via the bonding pads 50.

The contact plugs CCw are provided in the periphery of the stacked body 20 and stretch in the interlayer dielectric 25 in the Z direction. The contact plugs CCw are electrically connected between electrode films 21 (word lines WL) and wires 24. The contact plugs CCw are provided at staircase portions 2s, where the electrode films 21 are formed in a staircase pattern at end portions of the stacked body 20. The contact plugs CCw are electrically connected to the electrode films 21. The contact plugs CCw are provided to transmit a word line voltage from the CMOS chip 3 to the electrode films 21. As the material of the contact plugs CCw, for example, a metal such as copper or tungsten is used.

The contact plugs 29 are provided in the periphery of the stacked body 20 and stretch in the interlayer dielectric 25 in the Z direction. The contact plugs 29 are provided from at least a lower side of the stacked body 20 to at least an upper side of the stacked body 20.

The contact plugs 29 are electrically connected between the bonding pads 50 and wire 24. The contact plugs 29 are used to supply power or signals from the bonding pads 50 to the array chip 2 or the CMOS chip 3. As the material of the contact plugs 29, for example, a metal such as copper or tungsten is used. Examples of the power include a power voltage VDD, or a reference voltage (e.g., a ground voltage) VSS, which is lower than the power voltage VDD. The signals may be control signals from the outside or may be data to be written or read data.

In the present embodiment, the array chip 2 and the CMOS chip 3 are formed individually and bonded together at the bonding surface B1. Therefore, the transistors 31 are not provided in the array chip 2. The stacked body 20 (memory cell array 2m) is not provided in the CMOS chip 3.

Below the stacked body 20, the vias 28, the wires 23, and the wires 24 are provided. The wires 23 and 24 are embedded in the interlayer dielectric 25. The wires 24 are exposed on a surface of the interlayer dielectric 25, being substantially flush with the surface. The wires 23 and 24 are electrically connected to semiconductor bodies 210 and the like of the columnar bodies CL. As the material of the vias 28, the wires 23, and the wires 24, for example, a metal such as copper or tungsten is used. The stacked body 20, the vias 28, the wires 23, and the wires 24 are covered with and protected by the interlayer dielectric 25. As the material of the interlayer dielectric 25, for example, an insulation film such as a silicon oxide film is used.

The interlayer dielectric 25 and the interlayer dielectric 35 are bonded together at the bonding surface B1, and accordingly, the wires 24 and the wires 34 are joined together at the bonding surface B1, being substantially flush with each other. This causes the array chip 2 and the CMOS chip 3 to be electrically connected together via the wires 24 and the wires 34.

FIG. 14 is a plan view illustrating the stacked body 20. The stacked body 20 includes the staircase portions 2s and the memory cell array 2m. The staircase portions 2s are provided at the end portions of the stacked body 20. The memory cell array 2m is sandwiched between or surrounded by the staircase portions 2s. The slits ST are provided from a staircase portion 2s at one end of the stacked body 20 via the memory cell array 2m to a staircase portion 2s at another end of the stacked body 20. Slits SHE are provided at least in the memory cell array 2m. The slits SHE are shallower in the Z direction than the slits ST and stretch substantially parallel to the slits ST. The slits SHE electrically divide the electrode film 21 on the lower region side of the stacked body 20 for each of the drain-side selector gates SGD. As the material of the slits SHE, for example, an insulation film such as a silicon oxide film is used. The slits ST may include source lines that are electrically connected to the source layer BSL while being electrically isolated from the electrode films 21 of the stacked body 20.

A portion of the stacked body 20 sandwiched between every two adjacent slits ST illustrated in FIG. 14 is called a block (BLOCK). The block forms, for example, a minimum unit for data erasure. The slits SHE are each provided inside a block. A portion of the stacked body 20 between a slit ST and a slit SHE is called a finger. The drain-side selector gates SGD are partitioned into on a per-finger basis. For this reason, when data is written or read, a drain-side selector gate SGD can bring one finger in a block into a selected state.

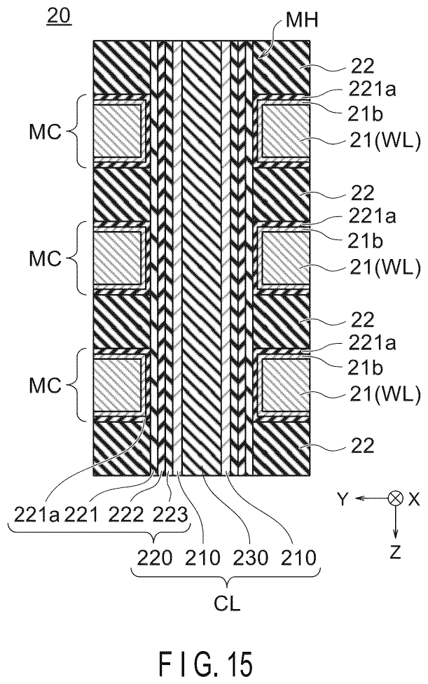

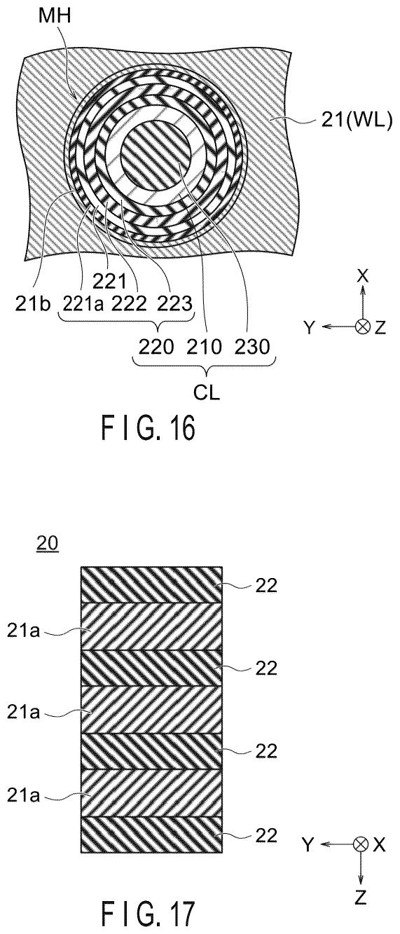

FIG. 15 and FIG. 16 are sectional views each exemplifying a memory cell in a three-dimensional structure. The plurality of columnar bodies CL are each provided in a memory hole MH provided in the stacked body 20. The columnar bodies CL penetrate the stacked body 20 from one end portion of the stacked body 20 along the Z direction and are provided in the stacked body 20, reaching the source layer BSL. The plurality of columnar bodies CL each include a semiconductor body 210, a memory film 220, and a core layer 230. Each columnar body CL includes a core layer 230 provided at the center portion of the columnar body CL, the semiconductor body (semiconductor layer) 210 provided around the core layer 230, and the memory film 220 provided around the semiconductor body 210. The semiconductor body 210 extends in the stacked body 20 in the stacking direction (the Z direction). The semiconductor body 210 is electrically connected to the source layer BSL. The memory film 220 is provided between the semiconductor body 210 and the electrode films 21 and includes charge trapping portions. A plurality of columnar bodies CL that are selected one by one from the respective fingers are connected to one bit line 23 in common via vias 28 in FIG. 16. The columnar bodies CL are provided in, for example, a region where the memory cell array 2m is present.

As illustrated in FIG. 16, the memory hole MH is, for example, in a circular or elliptic shape in an X-Y plane. Between an electrode film 21 and insulation films 22, a block insulation film 221a that partially forms the memory film 220 may be provided. The block insulation film 221a is made of, for example, silicon oxide or a metallic oxide. An example of the metallic oxide is an aluminum oxide. Between an electrode film 21 and insulation films 22 and between the electrode film 21 and the memory film 220, a barrier film 21b may be provided. The barrier film 21b is, for example, a layered film of titanium nitride and titanium in the case where, for example, the electrode film 21 is made of tungsten. The block insulation film 221a restrains the back tunneling of electric charge from the electrode film 21 toward the memory film 220. The barrier film 21b improves adhesiveness between the electrode film 21 and the block insulation film 221a.

The semiconductor body 210 is, for example, in a bottomed cylindrical shape. As the material of the semiconductor body 210, for example, polysilicon is used. The semiconductor body 210 is, for example, undoped silicon. Alternatively, the semiconductor body 210 may be made of a p-type silicon. The semiconductor body 210 serves as a channel of each of a drain-side selection transistor, memory cells MC, and source-side selection transistor. That is, the plurality of memory cells MC include storage regions between the semiconductor body 210 and electrode films 21 serving as the word lines WL and are stacked in the Z direction. One ends of a plurality of semiconductor bodies 210 in a single memory cell array 2m is electrically connected to the source layer BSL in common.

The memory film 220 includes, for example, a cover insulation film 221, a charge trapping film 222, a tunnel insulation film 223, and block insulation films 221a. The memory film 220 except the block insulation films 221a is provided between the inner wall of the memory hole MH and the semiconductor body 210. The memory film 220 is, for example, in a cylindrical shape. The charge trapping film 222 and the tunnel insulation film 223 stretch in the Z direction.

The cover insulation film 221 is provided between the insulation films 22 and the charge trapping film 222 and between the block insulation films 221a and the charge trapping film 222. The cover insulation film 221 contains, for example, silicon oxide. The cover insulation film 221 protects the charge trapping film 222 from etching when the sacrificial films (21a in FIG. 17) are replaced with the electrode films 21 (the replacement step).

The charge trapping film 222 is provided between the cover insulation film 221 and the tunnel insulation film 223. The charge trapping film 222 contains, for example, silicon nitride and includes trap sites that trap electric charge in the film. Portions of the charge trapping film 222 sandwiched between the electrode films 21 serving as the word lines WL and the semiconductor body 210 form storage regions of the memory cells MC as the charge trapping portions. The threshold voltage of each memory cell MC varies in accordance with the presence or absence of electric charge in the corresponding charge trapping portion or the amount of electric charge trapped in the charge trapping portion. In this manner, the memory cells MC retain information.

The tunnel insulation film 223 is provided between the semiconductor body 210 and the charge trapping film 222. The tunnel insulation film 223 contains, for example, silicon oxide, or silicon oxide and silicon nitride. The tunnel insulation film 223 serves as a potential barrier between the semiconductor body 210 and the charge trapping film 222. For example, when electrons are injected from the semiconductor body 210 into the charge trapping film 222 (writing operation) or when positive holes are injected from the semiconductor body 210 into the charge trapping film 222 (erasing operation), the electrons or the positive holes pass the potential barrier of the tunnel insulation film 223 (tunneling).

The core layer 230 embeds the inner space of the cylindrical semiconductor body 210. The core layer 230 is, for example, in a columnar shape. The core layer 230 contains, for example, silicon oxide, having insulation properties.

Next, the replacement step will be described.

FIG. 17 to FIG. 20 are sectional views illustrating an example of a replacement step in a manufacturing process of the array chip 2 according to the present embodiment.

First, as illustrated in FIG. 17, the stacked body 20 of the array chip 2 is formed by stacking sacrificial films 21a and insulation films 22 alternately in a −Z direction. As the material of the sacrificial films 21a, for example, a silicon nitride film is used. As the material of the insulation films 22, for example, a silicon oxide film is used.

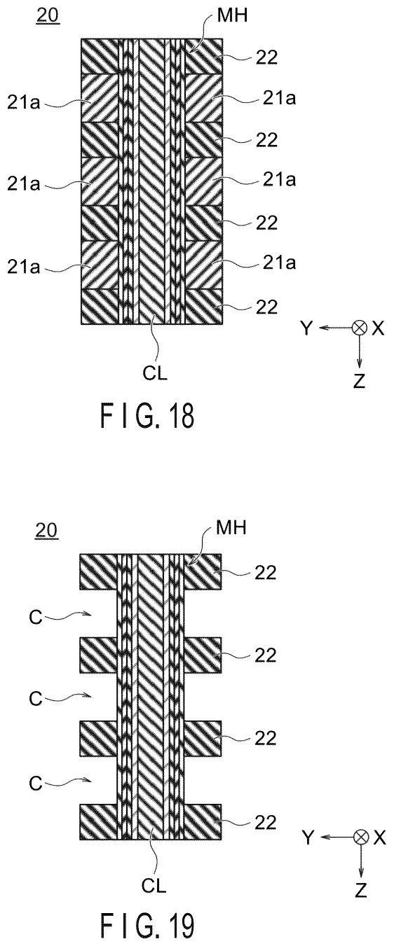

Next, a plurality of memory holes MH penetrating the stacked body 20 in the Z direction are formed by means of a lithography technology and an etching technology. Next, as illustrated in FIG. 18, columnar bodies CL are formed in the plurality of memory holes MH.

Next, the slits ST illustrated in FIG. 14 are formed in the stacked body 20 by means of a lithography technology and an etching technology. The slits ST are provided penetrating the stacked body 20 in the Z direction.

Next, the sacrificial films 21a are removed via the slits ST by means of a wet etching method. At this time, the sacrificial films 21a are selectively etched in an isotropic manner with the etching system according to the above embodiment. As illustrated in FIG. 19, this forms cavities C between the insulation films 22 adjacent in the Z direction (locations where the sacrificial films 21a were present). At this time, the insulation films 22 do not become depressed or collapse by the fluid mixture.

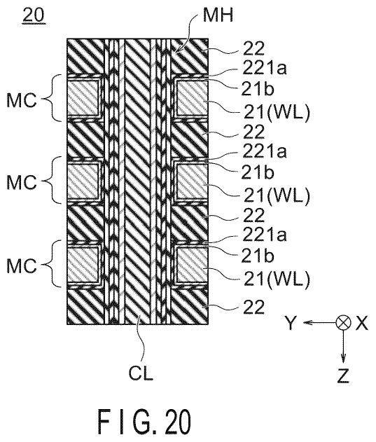

Next, the material of the block insulation films 221a, the material of the barrier film 21b (e.g., Ti, TiN), and the material of the electrode films 21 (e.g., tungsten) are deposited on the inner walls of the cavities C via the slits ST. This provides a structure illustrated in FIG. 20.

As seen from the above, it is possible to restrain the insulation films 22 in FIG. 19 from collapsing into the cavities C by replacing the sacrificial films 21a with the electrode films 21 with the etching system according to the above embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor manufacturing system, comprising:
a first fluid reservoir that retains a first fluid, the first fluid being including a first liquid with an adjusting substance added thereto, the adjusting substance having a property that adjusts a pH;
a first fluid supplier including a first pump that supplies the first fluid to a mixer;
a second fluid supplier including a second pump, the second fluid supplier causes a second fluid to turn into a supercritical fluid and supplies the supercritical fluid to the mixer;
a first heater that houses the mixer and heats the mixer;
a second heater that heats a chamber, the chamber being capable of housing a substrate; and
a fluid mixture supplier having a third pump that supplies the second heating mechanism with a fluid mixture into which the first fluid and the supercritical fluid are mixed in the mixer.

2. The semiconductor manufacturing system of claim 1, control circuitry configured to control the first fluid supplier to adjust a pH in accordance with a treatment temperature of a substrate that is subjected to treatment using the fluid mixture in the chamber.

3. The semiconductor manufacturing system of claim 2, wherein the control circuitry is configured to control the treatment temperature of the substrate to be between 413 K and 473 K, inclusive, and set the pH of the first fluid to be 11 to 8 at normal temperature and pressure.

4. The semiconductor manufacturing system of claim 2, wherein the control circuitry is configured to control the treatment temperature of the substrate to be between 473 K and 503 K, inclusive, and set the pH of the first fluid to be 8 to 6 at normal temperature and pressure.

5. The semiconductor manufacturing system of claim 2, wherein the control circuitry is configured to control the treatment temperature of the substrate to be between 553 K and 593 K, inclusive, and set the pH of the first fluid to be 3 to 1 at normal temperature and pressure.

6. The semiconductor manufacturing system of claim 1, wherein the second fluid includes carbon dioxide.

7. The semiconductor manufacturing system of claim 1, wherein the first liquid includes water.

8. The semiconductor manufacturing system of claim 1, wherein the adjusting substance is an amine which includes at least one of hexylamine, pyridine, aniline, ammonia, sodium hydroxide, potassium hydroxide, and calcium hydroxide.

9. The semiconductor manufacturing system of claim 1, wherein the adjusting substance includes at least one of acetic acid, formic acid, hydrochloric acid, sulfuric acid, nitric acid, phosphoric acid, oxalic acid, and benzoic acid.

10. The semiconductor manufacturing system of claim 2, wherein at normal temperature and pressure, an optimal value of the pH of the first fluid is given by Expression 1:
pH=−32.13×ln(T)+206.03 (Expression 1)
where T denotes a treatment temperature (K) of the substrate.

11. A method for manufacturing a semiconductor device in a semiconductor manufacturing system, the method comprising:
carrying a substrate into a chamber sized to accommodate the substrate, and heating the substrate with a first heating mechanism;
in a second heating mechanism that includes a mixer and heater, generating a first fluid by adding an adjusting substance to a first liquid, the adjusting substance being for adjusting a pH;
generating a fluid mixture by mixing the first fluid and a second fluid with the mixer, and turning the second fluid into a supercritical fluid; and
supplying the fluid mixture to the chamber and etching the substrate with the fluid mixture.

12. The method of claim 11, wherein the adjusting includes adjusting the pH in accordance with a treatment temperature of the substrate using the fluid mixture.

13. The method of claim 12, further comprising controlling the treatment temperature of the substrate to be between 413 K and 473 K, inclusive, and setting the pH of the first fluid to be 11 to 8 at normal temperature and pressure.

14. The method of claim 12, further comprising controlling the treatment temperature of the substrate to be between 473 K and 503 K, inclusive, and setting the pH of the first fluid to be 8 to 6 at normal temperature and pressure.

15. The method of claim 12, further comprising controlling the treatment temperature of the substrate to be between 553 K and 593 K, inclusive, and setting the pH of the first fluid to be 3 to 1 at normal temperature and pressure.

16. The method of claim 11, wherein the second fluid includes carbon dioxide.

17. The method of claim 11, wherein the first liquid includes water.

18. The method of claim 11, wherein the adjusting substance is an amine which includes at least one of hexylamine, pyridine, aniline, ammonia, sodium hydroxide, potassium hydroxide, and calcium hydroxide.

19. The method of claim 11, wherein the adjusting substance includes at least one of acetic acid, formic acid, hydrochloric acid, sulfuric acid, nitric acid, phosphoric acid, oxalic acid, and benzoic acid.

20. The method of claim 11, wherein the substrate is a substrate of a NAND flash memory.
